(19) United States
(12) Patent Application Publication
(10) Pub. No.: US 2007/0192050 A1
(43) Pub. Date: Aug. 16, 2007

(54) Interface control apparatus and setting method for an interface

(75) Inventors: Kenichi Douniwa, Asaka-shi (JP); Tsutomu Unesaki, Tokyo (JP)

Correspondence Address: BLAKELY SOKOLOFF TAYLOR & ZAFMAN, 1279 OAKMEAD PARKWAY, SUNNYVALE, CA, 94085-4040, US

(73) Assignee: Kabushiki Kaisha Toshiba

(21) Appl. No.: 11/699,671

(22) Filed: Jan. 29, 2007

(30) Foreign Application Priority Data
Jan. 30, 2006 (JP) P2006-020815

(51) Int. Cl. G01R 35/00

(52) U.S. Cl. 702/85

(57) ABSTRACT

According to one embodiment, an interface control apparatus controls an interface to which a calibration is required in use. The interface control apparatus includes an interface controller configured to drive the interface, a storage device that stores a predicted value of a setting value after the calibration is carried out on the interface, the setting value to be set to the interface controller, and a setting unit configured to set the setting value to the interface controller based on the predicted value stored in the storage device.

### CROSS-REFERENCE TO RELATED APPLICATIONS

This application is based upon and claims the benefit of priority from Japanese Patent Application No. 2006-020815, filed Jan. 30, 2006, the entire contents of which are incorporated herein by reference.

### BACKGROUND

1. Field

One embodiment of the invention relates to an interface control apparatus equipped to a component, and an interface setting method therefor, and particularly to a setting method for an interface to which calibration is required when it is used.

2. Description of the Related Art

A product such as an electronics device is frequently mounted in a housing while divided into some components (constituent elements). The respective components communicate with each other through an interface for connecting the respective components in order to deliver data between the components.

In recent electronics devices, a broad band communication is required even between components. In such broad-band interface, it is required to carry out calibration (correction) on the set value of the interface at the initial time or as occasion demands.

However, it is impossible to make the communication between the components through the interface concerned until the calibration is completed, and also it generally needs much time to complete the calibration, so that some disadvantage occurs in use of the equipment.

There has been proposed an information processing device in which a set value before stopped is stored, and this stored set value is used under initialization at the re-start time, so that the previous setting is restored without re-setting (see JP-A-2001-255954).

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a diagram showing an example of an interface control device according to a first embodiment;

FIG. 2 is a diagram showing an example of the operation flow of the interface control device according to the first embodiment;

FIG. 3 is a diagram showing another example of the operation flow of the interface control device according to the first embodiment;

FIG. 4 is a diagram showing an example of the interface control device according to a second embodiment;

FIG. 5 is a diagram showing an example of the operation flow of the interface control device according to the second embodiment; and

FIG. 6 is a diagram showing another example of the operation flow of the interface control device according to the second embodiment.

### DETAILED DESCRIPTION

Various embodiments according to the invention will be described hereinafter with reference to the accompanying drawings. In general, according to one embodiment of the invention, an interface control apparatus controls an interface to which a calibration is required in use. The interface control apparatus includes an interface controller configured to drive the interface, a storage device that stores a predicted value of a setting value after the calibration is carried out on the interface, the setting value to be set to the interface controller, and a setting unit configured to set the setting value to the interface controller based on the predicted value stored in the storage device.

### First Embodiment

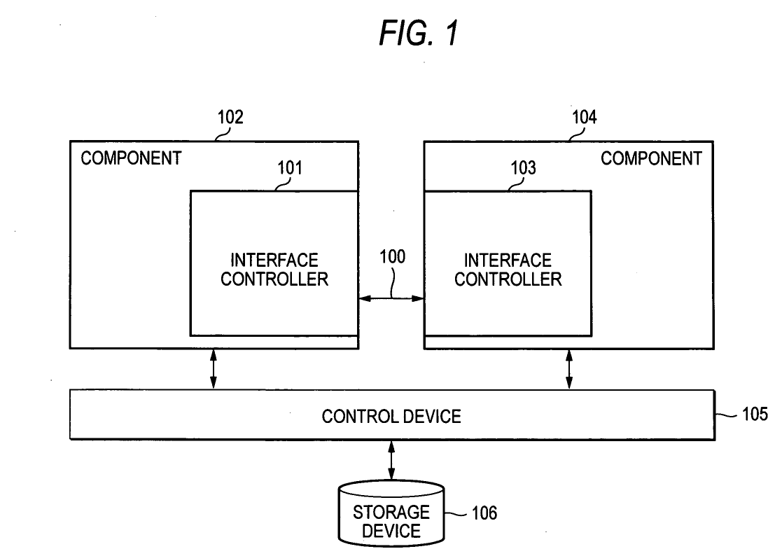

FIG. 1 is a diagram showing an example of an interface control device according to this embodiment. An interface 100, an interface controller 101, a component 102, an interface controller 103, a component 104, a control device 105 and a storage device 106 are shown in FIG. 1.

The interface 100 represents a communication medium or a communication system used for the communication between components. This is based on the assumption of a work for correcting a set value associated with an interface operation called as calibration to optimize the actuation state prior to the communication. As the speed of the interface gets higher, it is more strongly required that the set value is ever-shifting in accordance with the operation environment in order to bring out the capability of the interface at maximum. If this setting is not carried out, there might be a case where the performance of the interface cannot be brought out.

The interface controllers 101 and 103 are controllers for driving the interface 100. When to control the operation timing of the transfer of the interface, the efficiency would be normally lowered if such control is performed in communication devices that communicates using the operation timing. Therefore, the interface is provided with a dedicated controller so that the device side using the interface is not relied on the details of the actuation of the interface and that the communication can be made through the interface at a high speed.

Each of the components 102 and 104 represents LSI (semiconductor integrated circuit), a circuit board or a communication device which has a predetermined function, for example. It is required to communicate information for performing predetermined processing between these components. The communication is implemented through the interface 100. In this case, there are various modes in the configuration of the components or the like, and the interface can be used in conformity with the mode. This embodiment does not limit the type of the interface, however, it is based on the assumption of use of an interface to which calibration is required prior to use of the interface.

The control device 105 has a function of controlling the operation of the components 102 and 104 or the interface controllers 101 and 103. Here, the “control” contains at least supply or setting of the set value of the interface controllers 101 and 103 for driving the interface 100, and achievement of the set value.

For example, the storage device 106 includes an HDD (magnetic disk device), a semiconductor memory or the like which stores a set value achieved by the control device 105. The stored set value is read out by the control device 105 as occasion demands. As examples of the set value to be stored are considered a set value of the driving performance of an output buffer, a set value of slew rate, and set values associated with phase setting and termination when data latch is carried out at the input time.

The set value is determined to some extent in accordance with the interface and the combination of components, and thus the set value under a use state can be predicted in advance when the components to be connected to each other are fixed. Therefore, for example, the set value of the interface controller can be determined in advance at the factory shipment stage after a product is fabricated.

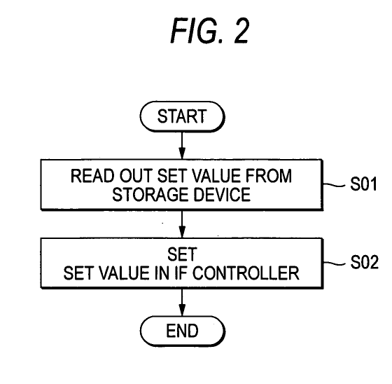

FIG. 2 shows an example of the operation flow of the interface control device according to this embodiment. In this operation flow, it is shown that a set value as a prediction value which would be achieved when calibration is carried out in the above construction is stored in the storage device 106 in advance.

The control device 105 first reads out from the storage device 106 values to be set in the interface controllers 101 and 103 of the interface 100 (step S01). These values are used by the respective interface controllers when the interface controllers 101 and 103 make communications through the interface 100. In the conventional technique, this value is determined by the interface controller every time calibration is carried out.

Next, the set value read out from the storage device 106 is set in the interface controllers 101 and 103 (step S02) At this time, the interface controllers 101 and 103 carries out the communication based on the interface 100 by using the set value stored in the storage device 106 in advance without carrying out calibration.

With this configuration, the time required for the calibration can be reduced, and thus the communication can be immediately started.

This processing is executed when the setting of the interface controller must be executed, for example, when the components 102 or 104 is powered on or reset.

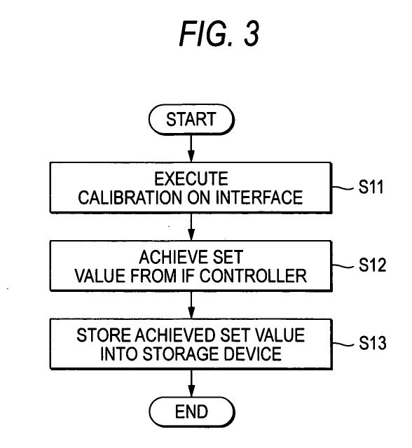

FIG. 3 is a diagram showing another example of the operation flow of the interface control device according to the embodiment. The operation flow is a standby operation to carry out calibration in the same manner as conventionally done on respective combinations of the interfaces and the interface controllers, so as to use the set values thus achieved as set values read out through the operation flow shown in FIG. 2.

First, the calibration of the interface 100 is executed (step S11).

Next, the control device 105 achieves the set value of the interface controllers 101 and 103 (step S12).

The achieved set value stores as the set value for the interface controllers 101 and 103 in the storage device 106 (step S13). This value is also read out and used at the initialization time of the interface controller at the next time.

The storage of the set value after the calibration in this operation may be carried out at the time when the use of the component is finished, periodically in use of the component or at the timing when the control device 105 perceives alteration of the component.

According to this configuration, the set value of the interface controller can be set on the basis of the set value after the actual calibration, and the value can be corrected to be more appropriate to the construction concerned as compared with a predicted set value.

This operation is carried out to correct the set value to a more appropriate value, and thus it is not necessarily carried out because no problem would occur even if a set value stored in the storage device 106 in advance is used.

### Second Embodiment

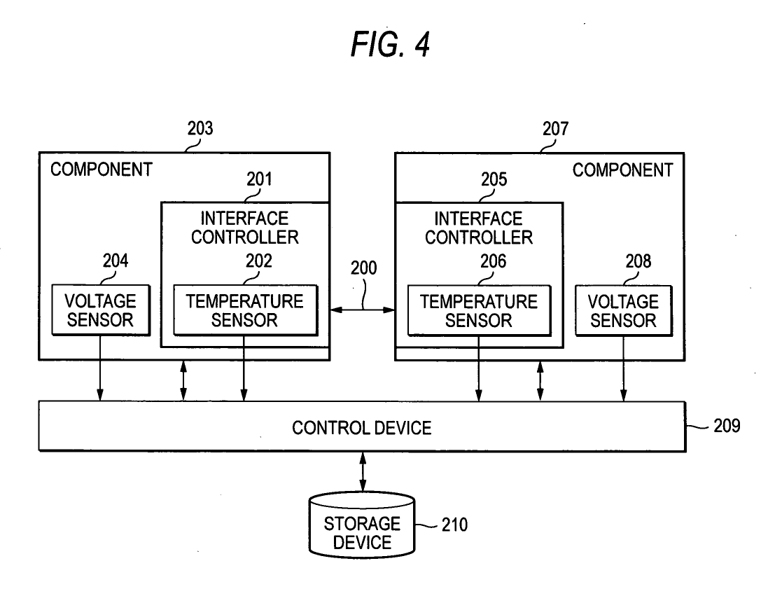

FIG. 4 is a diagram showing an example of the interface control device according to a second embodiment. FIG. 4 shows an interface 200, an interface controller 201, a temperature sensor 202, a component 203, a voltage sensor 204, an interface controller 205, a temperature sensor 206, a component 207, a voltage sensor 208, a control device 209 and a storage device 210.

The interface 200 represents a communication medium or a communication system used for the communication between components. This is based on the assumption of a work for correcting a set value associated with an interface operation called as calibration to optimize the actuation state prior to the communication. As the speed of the interface gets higher, it is more strongly required that the set value is set ever-shifting in accordance with the operation environment in order to bring out the capability of the interface at maximum. If this setting is not carried out, there might be a case where the performance of the interface cannot be brought out.

The interface controllers 201 and 205 are controllers for driving the interface 200. When to control the operation timing of the transfer of the interface, the efficiency would be normally lowered if such control is performed in communication devices that communicates using the operation timing. Therefore, the interface is provided with a dedicated controller so that the device side using the interface is not relied on the details of the actuation of the interface and also the communication can be made through the interface at a high speed.

The temperature sensors 202 and 206 are sensors for measuring the temperature of the interface controllers 201, 205, respectively. The reason why the temperature of the interface controllers is measured resides in that it is considered that when a constituent part whose electrical characteristic is fluctuated in accordance with the difference in temperature is used in an interface controller, the set values of the interface controllers 201 and 205 may be different in accordance with the temperature.

The components 203 and 207 represent LSI (semiconductor integrated circuit), a circuit board or a communication device which has a predetermined function, for example. It is required to communicate information for performing predetermined processing between these components. The communication is implemented through the interface 200. In this case, there are various modes in the configuration of the components or the like. The interface can be used in conformity with the mode. This embodiment does not limit the type of the interface. However, it is based on the assumption of use of an interface to which calibration is required prior to use of the interface.

The voltage sensors 204 and 208 are sensors for measuring the power source voltages supplied to the interfaces 201 and 205, respectively. The reason why the power source voltages are measured resides in that it is considered that when a constituent part whose electrical characteristic is fluctuated in accordance with the difference in voltage is used in an interface controller, the set values of the interface controllers 201 and 205 may be different in accordance with the voltage.

The control device 209 has a function of controlling the operation of the components 203 and 207 or the interface controllers 201 and 205. Here, the “control” contains at least supply or setting of the set value of the interface controllers 201 and 205 for driving the interface 200 and achievement of the set value.

The storage device 210 stores the set value achieved by the control device 209. For example, it is an HDD (magnetic disk device), a semiconductor memory or the like. The stored set value is read out by the control device 209 as occasion demands. The examples of the stored set value is as follows: a set value of driving performance of an output buffer, a set value of a slew rate, and set values associated with phase setting and termination when data latch is carried out at the input time, etc.

These set values may be considered to be determined to some extent in accordance with the interface and the combination of the components and also the use environment such as the temperature, the supplied voltage or the like. When the components to be connected to each other are fixed, the set value can be predicted in advance in prospect of a variation factor such as temperature, voltage or the like under the use environment. Therefore, the set value of the interface controller can be determined in advance at the factory shipment stage after a product is fabricated.

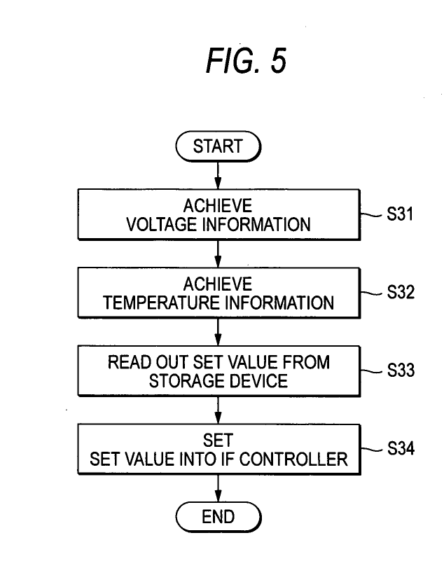

FIG. 5 is a diagram showing an example of the operation flow of the interface control device according to this embodiment. In this operation flow, a set value as a predicted value which is expected to be achieved through calibration in the above construction is stored in the storage device 210.

The control device 209 first achieves the information on the supplied voltage from the voltage sensors 204 and 208 (step S31).

Subsequently, the control device 209 achieves the information on the temperature of the interface controllers 201 and 205 from the temperature sensors 202 and 206 (step S32).

Subsequently, the control device 209 reads out from the storage device a value to be set in the interface controllers 201 and 205 of the interface 200 (step S33). This value is a value used by each interface controller when the communication is made between the interface controllers 101 and 103 through the interface 100. Conventionally, this value is determined through execution of calibration by the interface controller on a case-by-case basis.

The set value to be read out here is the value associated with the information achieved in the steps S31, S32. That is, if the information on the temperature or the voltage is varied, a different set value can be given.

Subsequently, the set value read out from the storage device 210 is set in the interface controllers 201 and 205 (step S34). The interface controllers 201 and 205 carries out the communication based on the interface 200 by using the set value stored in the storage device 210 in advance without executing calibration.

According to the above configuration, the time required for the calibration can be reduced while responding flexibly to the variation factor of the use environment at that time, and thus the communication can be immediately started.

This processing is carried out when the interface controller must be set, for example, in such a case that the components 203 or 207 is powered on or reset.

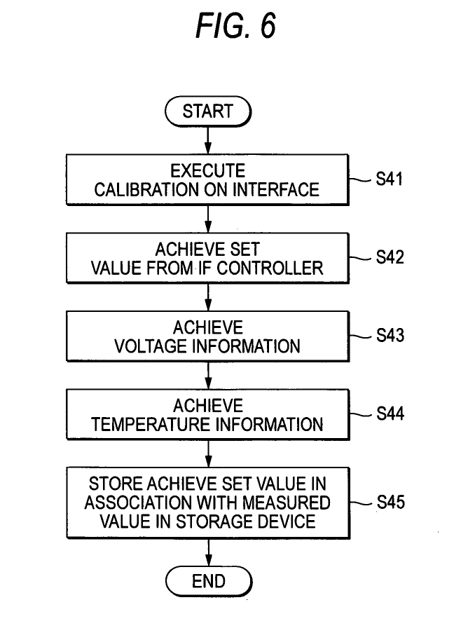

FIG. 6 is a diagram showing another example of the operation flow of the interface control device according to this embodiment. This operation flow is a standby operation to carry out calibration as conventionally done on the basis of the interface and the combination of the interface controllers and use the thus-achieved set value as a set value read out through the operation flow shown in FIG. 5.

First, the calibration of the interface 200 is executed (step S41).

Subsequently, the control device 209 achieves the set value of the interface controllers 201 and 205 (step S42).

Subsequently, the information on the supplied voltage is achieved from the voltage sensors 204 and 208 (step S43).

Furthermore, the information on the temperature of each interface controller is achieved from each of the temperature sensors 202 and 206 (step S44).

The set value thus achieved is stored as the set value for the interface controller 201 or 205 with respect to the voltage and temperature achieved in the steps S43 and S44 in the storage device 106 (step S45). This value is read out and used at the initialization time of the interface controller or the like.

The storage of the set value after the calibration in the above operation may be carried out at the time when the use of the component is finished, periodically in use of the component or at the timing when the control device 210 perceives alteration of the component.

According to the above configuration, the set value of the interface controller can be set on the basis of the set value after the actual calibration, and the value can be corrected to be more appropriate to the construction concerned as compared with a predicted set value.

This operation is carried out to correct the set value to a more appropriate value, and thus it is not necessarily carried out because no problem would occur even if a set value stored in the storage device 210 in advance is used.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An interface control apparatus for controlling an interface to which a calibration is required in use, comprising:
an interface controller configured to drive the interface;
a storage device that stores a predicted value of a setting value after the calibration is carried out on the interface, the setting value to be set to the interface controller; and
a setting unit configured to set the setting value to the interface controller based on the predicted value stored in the storage device.

2. The interface control apparatus according to claim 1,
wherein, after the calibration is carried out on the interface, the setting unit reads out the setting value in the interface controller and stores the setting vale in the storage device in place of the predicted value.

3. The interface control apparatus according to claim 1, further comprising: a temperature sensor that measures a temperature at a predetermined point in the interface controller;
wherein the setting unit sets the setting value based on the predicted value corresponding to temperature information measured by the temperature sensor.

4. The interface control apparatus according to claim 1, further comprising: a voltage sensor that measures a power source voltage supplied to the interface controller;
wherein the setting unit sets the setting value based on the predicted value corresponding to voltage information measured by the voltage sensor.

5. A setting method for an interface to which a calibration is required in use,
storing a predicted value of a setting value after the calibration is carried out on the interface, the setting value to be set to an interface controller for driving the interface; and
setting the setting value to the interface controller based on the predicted value stored in the storage device, when the interface is required to be set.

6. The setting method according to claim 5, further comprising:
reading out the setting value in the interface controller after the calibration is carried out on the interface; and
storing the setting value in the storage device in place of the predicted value.

7. The setting method according to claim 5, further comprising: measuring a temperature at a predetermined point in the interface controller;
wherein the setting step includes setting the setting value based on the predicted value corresponding to measured temperature information.

8. The setting control according to claim 5, further comprising: measuring a power source voltage supplied to the interface controller;
wherein the setting step includes setting the setting value based on the predicted value corresponding to measured voltage information.
